(19) United States
(12) Patent Application Publication
(10) Pub. No.: US 2021/0084743 A1
(43) Pub. Date: Mar. 18, 2021

(54) MICROWAVE PLASMA DEVICE

(71) Applicant: Ralf SPITZL, Troisdorf (DE)

(72) Inventor: Ralf SPITZL, Troisdorf (DE)

(21) Appl. No.: 16/960,992

(22) PCT Filed: Dec. 21, 2018
(86) PCT No.: PCT/EP2018/000582

§ 371 Date: Jul. 9, 2020

(30) Foreign Application Priority Data
Jan. 19, 2018 (DE) 10 2018 000 401.6

(51) Int. Cl. H05H 1/46; H01J 37/32

(52) U.S. Cl. CPC H05H 1/46; H01J 37/32201; H01J 37/3222

(57) ABSTRACT

A microwave plasma device includes a treatment space and a number of two or more microwave semiconductors. The microwave semiconductors are attached to the treatment space in such a way that the microwaves of a microwave semiconductor only interfere with the microwaves of other microwave semiconductors when in the treatment space.

The invention relates to a microwave plasma device and a method for operating a microwave plasma device.

Microwave applicators are used in various areas of industrial use. For example, they are used in heating processes for food, plastics, rubber or other substances. The technical field considered here is the use of microwave applicators to generate microwave plasmas for various plasma applications such as etching processes, cleaning processes, modification processes or coating processes. Typical frequencies for microwaves are in the range from 300 MHz to 300 GHz.

There are various microwave generators for generating microwaves. As a rule, magnetrons are used for the aforementioned applications.

As an alternative to a magnetron, power semiconductors can be used for microwave generation in plasma applications. However, these have only comparatively low powers in the order of a few 100 W. When using power semiconductors for microwave generation at high powers, several power semiconductors for microwave generation can be interconnected via a combiner and then coupled onto a rectangular waveguide. The rectangular waveguide then serves as a microwave input-coupling means or as a generator for the plasma source. Such power semiconductors for microwave generation are referred to below as “microwave semiconductors”.

In order to couple high powers into microwave applicators uniformly, DE 19600223 A1 and DE 19608949 A1, for example, describe, for instance, microwave distributors in the form of a ring or coaxial resonator which are connected upstream of a treatment space in order to realize a uniform coupling of the microwave power from different directions into said treatment space. A disadvantage of this type of input-coupling is that the power input-coupling from the power-supplying structure decreases in uniformity due to changing loads in the treatment space.

The object of the present invention was to overcome the disadvantages of the prior art and to provide a microwave plasma device and a method for operating a microwave plasma device, by means of which a uniform coupling of power into a treatment space is made possible.

This object is achieved by a microwave plasma device and a method according to the claims.

According to the invention, the object of power input-coupling is achieved in that a plurality of microwave semiconductors are attached to a treatment space of a microwave plasma device in such a way that they couple the microwaves directly into the treatment space. The term “direct(ly)” means that the microwaves of the individual microwave semiconductors are not superposed with one another prior to irradiation. Therefore, in contrast to the prior art, the microwaves are coupled out from the microwave semiconductors individually. The term “direct(ly)” does not exclude that the microwave semiconductors can also couple the microwaves into the treatment space via guiding structures.

The treatment space is configured in such a way that a plasma treatment can take place therein. In this regard, the treatment space is also synonymously referred to in the description as a “plasma chamber”.

A microwave plasma device according to the present invention, in particular a microwave plasma device for generating plasmas excited by microwaves, comprises a treatment space and a number of at least two or more microwave semiconductors. It is characterized in that the microwave semiconductors are attached to the treatment space in such a way that the microwaves of a (in particular of each) microwave semiconductor only interfere with the microwaves of other microwave semiconductors when in the treatment space.

For example, a microwave semiconductor may couple the microwaves into the treatment space via antennas. However, it is also possible for a microwave semiconductor to couple the microwaves into the treatment space via a feed with corresponding coupling points, wherein no other microwave semiconductor couples microwaves into this feed. Hence, the feed does not serve as a combiner. As necessary, the frequency ratio and phase ratio of the individual microwave semiconductors can be coupled to one another.

Although, as according to the invention, only a single microwave semiconductor needs to fulfil the abovementioned condition and other microwave semiconductors can theoretically be connected via a combiner, it is particularly preferred for each microwave semiconductor to couple its microwaves into the treatment space in the manner according to the invention, that is to say without microwaves interfering with one another before they have been coupled in.

The preferred microwave semiconductors have a power of several 10 W up to several 100 W, wherein a plurality of microwave semiconductors can be connected, preferably on circuit boards, in order to achieve a higher total power, which is in particular below 1000 W. Microwaves are preferably coupled out from these boards by means of a coaxial conductor. In particular, a plurality of microwave semiconductors for microwave generation or a plurality of the aforementioned circuit boards can be interconnected in terms of power. Because of its function, a circuit board having a plurality of microwave semiconductors is regarded here as a single “microwave semiconductor”.

According to the present invention, a plurality of microwave semiconductors are used in the present invention for microwave generation and microwave input-coupling. The advantage of the microwave semiconductors lies in their simple and robust design and in the property that both frequency and phase of the individual microwave generators can be adjusted.

In a method according to the present invention for operating a microwave plasma device (preferably of the aforementioned type), that is, a device for generating plasmas excited by microwaves, the microwaves of a (in particular of each) microwave semiconductor are coupled into a treatment space, by means of a number of two or more microwave semiconductors, in such a way that they only interfere with the microwaves of other microwave semiconductors when in the treatment space.

The microwaves are preferably coupled out from a microwave semiconductor via an antenna, preferably a rod antenna. For this purpose, the microwave semiconductor in question comprises an antenna via which the microwaves generated by the microwave semiconductor are coupled out from the latter. A rod antenna is preferably realised as an extension of the inner conductor of the output-coupling means coupling out from the microwave semiconductor. This output-coupling means is often configured coaxially.

The microwaves can be fed from the microwave semi-conductors into the treatment space directly via the aforementioned antennas. Depending on the application, however, it may be advantageous for this feed to take place indirectly.

In such an indirect case, the microwaves are fed from a microwave semiconductor into the treatment space preferably via a further coupling element or via a wave converter. In this case, the microwaves from the microwave semiconductor are preferably coupled into such a coupling element. A coupling element preferably comprises a rectangular, oval or round waveguide.

From the coupling element, the microwaves are coupled into the treatment space, preferably via a further antenna arrangement. Basically, the shape of an antenna of this antenna arrangement can be selected as desired, in accordance with the intended embodiment. A preferred antenna for coupling the microwaves into the treatment space is a slot antenna, a rod antenna or a hole coupler.

The treatment space is preferably divided into two regions, in particular by means of a wall which is made of a dielectric material or has a dielectric window. Quartz glass recipients are preferred for this purpose. The region into which the microwaves are not coupled directly is used as a treatment space or plasma chamber. This serves to protect the microwave sources.

In a preferred embodiment of the device, the treatment space can be configured in the form of a resonator structure, for example a cylindrical, rectangular, spherical, ellipsoidal, coaxial resonator or as a combination of these structures. This has the advantage that a resonant microwave can be produced in its interior.

The treatment space, that is, the plasma chamber, can comprise a sample receiving unit and/or a bias electrode. A combination thereof has the advantage that elements of the plasma can be directed specifically onto a sample disposed on the sample receiving unit, by means of a suitable potential between the bias electrode and the sample receiving unit.

Those elements by means of which the microwaves are introduced into the treatment space, that is to say, for example, the antennas of the microwave semiconductors in the case of direct input-coupling or the elements of the antenna arrangement in the case of indirect input-coupling, can be referred to as microwave input-coupling points, since the microwaves are coupled into the treatment space via said microwave input-coupling points.

Depending on the application, the microwave input-coupling points can be distributed in the treatment space as desired. The microwave input-coupling points are preferably located in the treatment space in one plane or in two or more planes.

Although input coupling of only one microwave frequency can be advantageous depending on the application, it may be advantageous in other applications to couple in microwaves of different frequencies. A group of the microwave semiconductors is preferably configured in such a way that these microwave semiconductors emit microwaves of the same frequency, or in such a way that microwaves of the same frequency are coupled into the treatment space. Microwave semiconductors of such a group are also referred to herein as “frequency-coupled” microwave semiconductors. In this case, all microwave semiconductors of the microwave plasma device can be in this group, so that all microwave semiconductors are frequency-coupled, but, depending on the application, individual microwave semiconductors, or further groups of microwave semiconductors frequency-coupled to one another, which emit microwaves having other frequencies than the abovementioned group can also be present. Thus, depending on the application, different groups, each having two or more frequency-coupled microwave semiconductors, can be present, wherein the microwave frequencies of the different groups are in each case different.

Even though an unpulsed microwave emission can be advantageous depending on the application, it may be advantageous in other applications to couple in microwave pulses. According to a preferred embodiment, a microwave semiconductor in this respect is configured to be excited in a pulsed manner or to couple in microwaves in a pulsed manner. A group of the microwave semiconductors is preferably configured in such a way that they are pulsed synchronously or that temporally identical microwave pulses are coupled into the treatment space. Microwave semiconductors of such a group are also referred to herein as “pulse-coupled” microwave semiconductors. In this case, all microwave semiconductors of the microwave plasma device can be in this group, so that all microwave semiconductors are pulse-coupled, but, depending on the application, individual microwave semiconductors or further groups of microwave semiconductors pulse-coupled to one another, which emit microwaves with other pulses than the abovementioned group can also be present. Depending on the application, different groups, each having two or more pulse-coupled microwave semiconductors, can thus be present, wherein the microwave pulses of the different groups are in each case different.

The microwaves can thus be coupled in in a pulsed or unpulsed manner, as required. Any desired pulse shapes are possible. The pulse sequence of individual microwave semiconductors in relation to one another can take place, for example, in groups, in a temporally offset manner, or else simultaneously.

A group of the microwave semiconductors is preferably configured in such a way that they emit microwaves of the same microwave power, or that microwaves of the same power couple into the treatment space. Microwave semiconductors of such a group are also referred to herein as “power-coupled” microwave semiconductors. In this case, all microwave semiconductors of the microwave plasma device can be in this group, so that all microwave semiconductors are power-coupled, but, depending on the application, individual microwave semiconductors, or further groups of microwave semiconductors power-coupled to one another, which emit microwaves with a another power than the above-mentioned group can also be present. Hence, depending on the application, different groups, each having two or more power-coupled microwave semiconductors, can be present, wherein the microwave power of the different groups is in each case different.

The power coupled in is preferably variable over time. This has the advantage that a complex control of a microwave treatment with clearly defined power curves is possible.

A group of microwave semiconductors is preferably configured in such a way that they emit microwaves of the same phase, or microwaves of the same phase are excited or coupled in. Microwave semiconductors of such a group are also referred to herein as “phase-coupled” microwave semiconductors. In this case, all microwave semiconductors of the microwave plasma device can be in this group, so that all microwave semiconductors are phase-coupled to one another, but, depending on the application, individual microwave semiconductors, or further groups of microwave semiconductors coupled to one another, which emit microwaves having another phase than said group can also be present. Thus, depending on the application, different groups, each having two or more phase-coupled microwave semiconductors, can be present, wherein the phases of the different groups are in each case different and/or vary over time.

The microwave semiconductors are preferably configured to emit microwaves having linear or circular polarization, or they are configured and positioned such that the microwaves coupled in for microwave generation are linearly or circularly polarized. In this case, a group of the microwave semiconductors is configured in such a way that they emit microwaves of the same polarization, or that microwaves of the same polarization are excited or coupled in. Microwave semiconductors of such a group are also referred to herein as “polarization-coupled” microwave semiconductors. In this case, all microwave semiconductors of the microwave plasma device can be in this group, so that all microwave semiconductors are coupled to one another, but, depending on the application, individual microwave semiconductors, or further groups of microwave semiconductors polarization-coupled to one another, which emit microwaves having another polarization than said group can also be present. Thus, depending on the application, different groups, each having two or more polarization-coupled microwave semiconductors can be present, wherein the polarizations of the different groups are in each case different and/or vary over time.

The microwave device is particularly suitable for use in plasma sources, but it is also suitable for non-plasma-related use, in particular in the food, chemical or pharmaceutical industries.

It is pointed out that the indefinite article “a” or “an” may also comprise a plurality and should be understood as meaning “at least one”. However, the singular is not explicitly excluded.

Examples of preferred embodiments of the microwave plasma device according to the invention are schematically illustrated in the figures.

FIG. 1 shows a top view of a preferred embodiment.

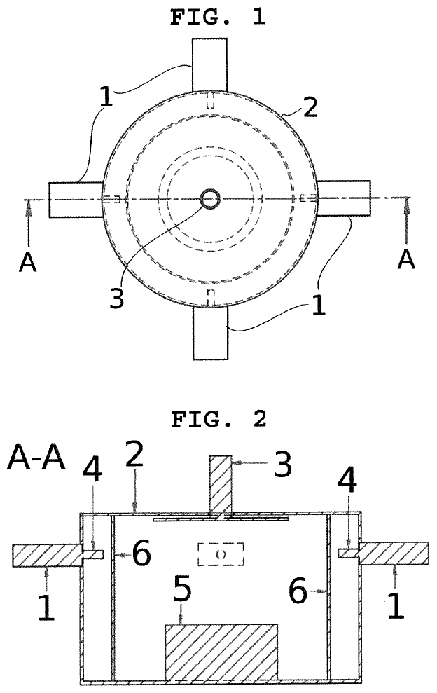

FIG. 2 shows a sectional image of the embodiment according to FIG. 1 in a side view.

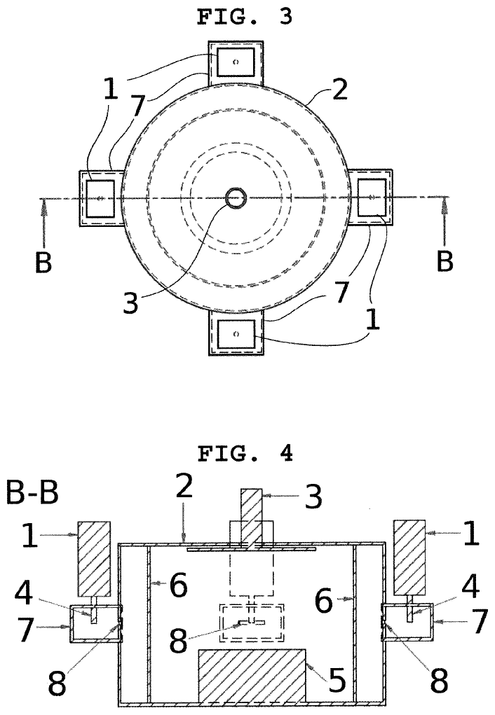

FIG. 3 shows a top view of another preferred embodiment.

FIG. 4 shows a sectional image of the embodiment according to FIG. 3 in a side view.

All components of the device according to the invention can also be present more than once. Only those components which are necessary or helpful for understanding the invention are illustrated. Thus, for example, further components which are known to the person skilled in the art, and their embodiments, are not shown in the Figures; such components are, for example, gas inlet and gas outlet, pump, pressure control unit, control, material locks, or corresponding components.

FIG. 1 shows an illustration of a preferred embodiment of the microwave plasma device from above. A treatment space 2, which is designed as a cylinder made of metal (for example brass, copper or aluminium) with a base and a cover and can serve as a resonator, is shown in the centre. Although this embodiment of the treatment space 2 in the form of a cylinder resonator is particularly preferred, spherical resonators, ellipsoidal resonators, rectangular resonators or mixed forms thereof can also offer advantages, depending on the application.

Four microwave semiconductors 1 are arranged equidistantly around the treatment space 2. If required, the number of microwave semiconductors 1 can be both increased and lowered. A bias electrode 3 can be seen in the centre of the treatment space 2. The treatment space 2 and two microwave semiconductors 1 are traversed centrally by the section plane A-A.

The components indicated by dashed lines in the drawing are not designated in detail here for reasons of a better overview. They are explained in more detail in the context of FIG. 2.

FIG. 2 shows the sectional plane A-A of the embodiment according to FIG. 1 in a side view. It can be seen here that input coupling of the microwaves from a microwave semiconductor 1 is in each case achieved via a rod antenna 4, which is configured, for example, as an extension of the inner conductor of the coaxial output-coupling means coupling out from the microwave semiconductor 1 into the treatment space 2.

A dielectric wall element 6, for example a quartz glass cylinder, divides the treatment space 2 in such a way that, depending on the application, a corresponding gas atmosphere having a desired gas composition and pressure can be adjusted in the region located in the interior of the dielectric wall element 6. The dielectric wall element 6 can be configured as a complete partition wall or else as a window in an otherwise non-dielectric wall.

A sample receiving unit 5 is located under the bias electrode 3, wherein the bias electrode 3 and the sample receiving unit 5 can be designed to be displaceable along the cylinder axis of the treatment space 2, that is to say upwards and downwards in the Figure. A bias voltage can be applied between the bias electrode 3 and the sample receiving unit 5 in order to direct plasma species (e.g. ions or electrons) onto the sample receiving unit 5.

FIG. 3 shows an illustration of a further preferred embodiment of the microwave plasma device from above. As in FIG. 1, four microwave semiconductors 1 are again arranged equidistantly around a treatment space 2. The bias electrode 3 can also be seen again in the centre of the treatment space 2. In contrast to FIG. 1, coupling elements 7 are shown in this Figure, each at the position of a microwave semiconductor 1. The treatment space 2 and two microwave semiconductors 1 are traversed centrally by the sectional plane B-B.

FIG. 4 shows the sectional plane B-B of the embodiment according to FIG. 3 in side view. As in the preceding example, input coupling of the microwaves from a microwave semiconductor 1 is achieved via, in each case, a rod antenna 4. In contrast to FIG. 2, the microwaves are coupled in from the microwave semiconductor 1 via the rod antenna 4, into a coupling element 7. Here, the coupling element 7 is configured as a rectangular waveguide element and converts the coaxial microwave feed into a rectangular waveguide wave. The latter is coupled into the treatment space 2 by means of coupling slots 8. In modification of this embodiment, there may be more or fewer microwave feeds composed of microwave semiconductor 1, rod antenna 4, coupling element 7 and coupling slots 8.

In the Figure, the coupling points 7 for coupling the microwaves into the treatment space or the microwave feeds lie in a plane. An arrangement of the coupling points or microwave feeds in a plurality of planes is also possible. In this way, higher powers or better homogeneity levels, for example for a plasma, of the irradiated microwave radiation can be obtained.

For example, the preferred embodiments of FIGS. 1 and 2 or 3 and 4 represent a microwave plasma device for generating a plasma. As already mentioned above, the dielectric wall element 6 can be a quartz glass recipient which partitions off an internal plasma chamber, said internal plasma chamber serving as a volume for carrying out a plasma treatment. The desired process conditions, such as, for example, gas composition, gas pressure or microwave power, can be set in the plasma chamber.

FIGS. 1 and 2 show a preferred way of coupling microwaves into the treatment space 2, i.e. direct input-coupling from the coaxial outlet. The inner conductor of the microwave semiconductor 1 couples-in the case shown, in the form of a rod antenna 4-into the treatment space 2.

FIGS. 3 and 4 show a further preferred way of coupling microwaves into the treatment space 2, i.e. the indirect input-coupling from the coaxial outlet.

Here, microwaves are converted into waveguide waves of any type via coupling elements 7, for example rectangular waveguides or circular waveguides, and then fed to the treatment space via the coupling slots 8. The way in which power is coupled in can thus be adapted to the structure of the treatment space 2.

Input coupling of the microwaves via the various microwave semiconductors 1 preferably takes place at the same frequency and phase but can also be adapted to that of the microwave plasma device if required.

An advantage of the embodiment according to the invention is that circulators and tuning elements in the feed of the microwaves to the treatment space can, but need not, be dispensed with.

The microwaves can be coupled in in a pulsed or unpulsed manner, as required. The power can vary between different power levels, i.e. it does not have to vary between 0 and 100%, but can be pulsed, for example, between 20% and 80%.

The polarization of the microwaves (e.g. linear, circular or elliptical) of the individual microwave semiconductors or microwave feeds can be implemented so as to be identical. Depending on the application, the polarization of different microwave semiconductors can also be selected so as to be different, or else so as to change over time.

The various input coupling options (pulsed, polarized, phase or frequency ratio) can also be combined as required.

### LIST OF REFERENCE NUMERALS

1 Microwave semiconductor
2 Treatment space
3 Bias electrode
4 Rod antenna
5 Sample-receiving unit
6 Dielectric wall element
7 Coupling element
8 Coupling slots

1-10. (canceled)

11. A microwave plasma device, comprising a treatment space (2) configured as a resonator structure and a number of two or more microwave semiconductors (1), wherein the microwave semiconductors (1) are attached to the treatment space (2) in such a way that the microwaves of each one of the microwave semiconductors only interfere with the microwaves of other microwave semiconductors (1) when in the treatment space, and in that output coupling of the microwaves from the microwave semiconductors (1) is effected via, in each case, an antenna (4), and in that the microwave plasma device is configured in such a way that the microwaves are fed from the antennas (4) into the treatment space (2) via, in each case, a further coupling element (7) and a further antenna arrangement comprising antennas (8).

12. A microwave plasma device according to claim 11, wherein the microwaves are coupled out from at least one microwave semiconductor via a rod antenna, wherein a rod antenna is preferably configured as an extension of the inner conductor of the, in particular coaxial, output-coupling means coupling out from the microwave semiconductor.

13. A microwave plasma device according to claim 11, wherein the microwave plasma device comprises rectangular, oval or round waveguides and/or couplers as further coupling elements (7) into which the microwaves are initially coupled, and in that the antennas (8) of the further antenna arrangement, from which the microwaves are coupled into the treatment space, are preferably slot antennas, rod antennas or hole couplers.

14. A microwave plasma device according to claim 11, wherein the treatment space (2) is divided into two regions, in particular by means of a dielectric wall element (6) which is a wall or a window, wherein said treatment space is configured as a cylindrical, rectangular, spherical, ellipsoidal, coaxial resonator, or as a combination thereof

15. A microwave plasma device according to claim 11, wherein microwave input-coupling points in the treatment space lie in at least one plane.

16. A microwave plasma device according to claim 11, wherein a group of the microwave semiconductors is frequency-coupled, wherein preferably all microwave semiconductors are frequency-coupled to one another, and wherein individual microwave semiconductors or further groups of microwave semiconductors frequency-coupled to one another are present which emit microwaves having other frequencies than the aforementioned group.

17. A microwave plasma device according to claim 11, wherein a microwave semiconductor is configured to be excited in a pulsed manner, wherein preferably a group of the microwave semiconductors is pulse-coupled, and wherein all microwave semiconductors of the microwave plasma device are pulse-coupled to one another, or individual microwave semiconductors or further groups of microwave semiconductors pulse-coupled to one another are present which emit microwaves with other pulses than the aforementioned group.

18. A microwave plasma device according to claim 11, wherein a group of microwave semiconductors is power-coupled, wherein the power coupled in is preferably variable over time, and wherein preferably all microwave semiconductors of the microwave plasma device are in this group, or individual microwave semiconductors or further groups of microwave semiconductors power-coupled to one another are present which emit microwaves having a different power than the aforementioned group.

19. A microwave plasma device according to claim 11, wherein the microwave semiconductors are configured to emit microwaves having linear or circular polarization, wherein preferably a group of the microwave semiconductors is configured such that these microwave semiconductors emit microwaves of the same polarization.

20. A method for operating a microwave plasma device according to claim 11, wherein the microwaves of each one of the microwave semiconductors are coupled into the treatment space in such a way that they only interfere with the microwaves of other microwave semiconductors when in the treatment space.
